(19) United States
(12) Patent Application Publication
(10) Pub. No.: US 2008/0030946 A1
(43) Pub. Date: Feb. 7, 2008

(54) Drawable tray assembly

(75) Inventor: Shao-Ming Lee, Nan-Tou Hsien (TW)

Correspondence Address: FROMMER LAWRENCE & HAUG, 745 FIFTH AVENUE- 10TH FL., NEW YORK, NY, 10151, US

(73) Assignee: UNIVERSAL SCIENTIFIC INDUSTRIAL CO., LTD.

(21) Appl. No.: 11/796,351

(22) Filed: Apr. 27, 2007

(30) Foreign Application Priority Data
Aug. 3, 2006 (TW) TW 095213674

(51) Int. Cl. H05K 5/02

(52) U.S. Cl. 361/685

(57) ABSTRACT

A drawable tray assembly includes: a tray body having a front end plate formed with a first engaging member; a pivot joint; and a handle including an elongated metal plate pivoted to the front end plate through the pivot joint to permit rotation of the handle relative to the tray body. The handle further includes a face cover mounted slidably on the metal plate, formed with a second engaging member which is releasably engageable with the first engaging member, and slidable relative to the metal plate.

### BACKGROUND OF THE INVENTION

1. Field of the Invention

The invention relates to a drawable tray assembly, more particularly to a drawable tray assembly for supporting a data storage device.

2. Description of the Related Art

Referring to FIG. 1, a conventional drawable tray assembly 1 for supporting a data storage device, such as a hard disk 2, etc., is adapted to be inserted into a storage casing (not shown), and usually includes a tray body 11 and a plastic handle 12. The tray body 11 has a front end plate 111 provided with a slidable engaging member 13. The handle 12 has a pivot end pivoted to an end of the front end plate 111 of the tray body 11, and a free end formed with an engaging element 121 to engage releasably the slidable engaging member 13. In this manner, the handle 12 is rotatable relative to the tray body 11 to an inclined position relative to the front end plate 111 so as to facilitate drawing operation of the tray body 11 out of the storage casing.

Since the handle 12 is made from a plastic material, the pivot end of the handle 12 tends to wear and break after a period of use.

FIG. 2 illustrates another conventional drawable tray assembly 3 that includes a tray body 31 adapted to support the data storage device 2 and having a front end plate 311 that is provided with a slidable first engaging member 33, and a handle 32. The handle 32 has a metal plate 321 pivoted to an end of the front end plate 311 of the tray body 31, and a plastic plate 323 secured to the metal plate 321 and formed with a second engaging member 322 for engaging the first engaging member 33. Although the drawable tray assembly 3 can eliminate the aforesaid drawbacks of the drawable tray assembly 1, assembly of the first engaging member 33 to the tray body 3, assembly of the metal plate 321 and the plastic plate 323, and assembly of the handle 32 to the tray body 31 are time-consuming and increase the manufacturing costs.

### SUMMARY OF THE INVENTION

Therefore, the object of the present invention is to provide a drawable tray assembly that can overcome the aforesaid drawbacks associated with the prior art.

Accordingly, a drawable tray assembly of this invention is adapted for supporting a data storage device thereon. The drawable tray assembly is insertable into an accommodating slot of a storage casing, and comprises: a tray body having a front end plate that is formed with a first engaging member, the tray body being adapted to support the data storage device thereon; a pivot joint; and a handle including an elongated metal plate that has a front side and that is pivoted to the front end plate of the tray body through the pivot joint so as to permit the handle to be rotatable relative to the tray body, the handle further including a face cover that covers and that is mounted slidably on the front side of the metal plate, that is co-rotatable with the metal plate, and that is formed with a second engaging member which is releasably engageable with the first engaging member.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic top view of a conventional drawable tray assembly;

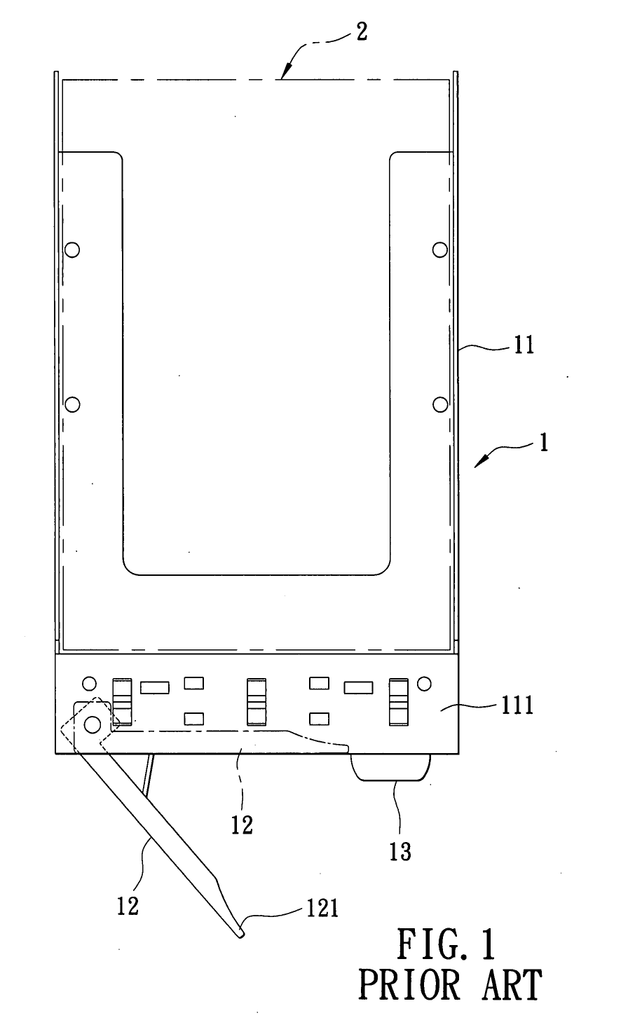

FIG. 2 is a schematic top view of another conventional drawable tray assembly;

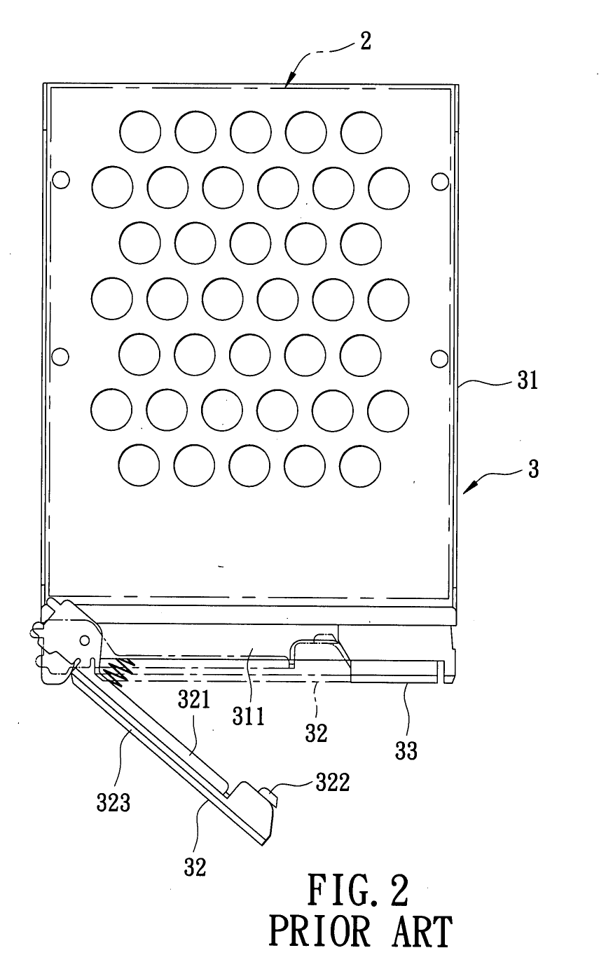

FIG. 3 is a fragmentary perspective view of the preferred embodiment of a drawable tray assembly according to the present invention, which is insertable into a storage casing;

FIG. 4 is an exploded perspective view of the preferred embodiment;

FIG. 5 is an assembled perspective view of the preferred embodiment;

FIG. 6 is a perspective view illustrating a state where a handle is disposed at a non-stacked position relative to a tray body of the preferred embodiment;

FIG. 7 is a fragmentary sectional view of the preferred embodiment to illustrate a state where the handle is disposed at the non-stacked position and where a face cover is disposed at a first position;

FIG. 8 is a fragmentary sectional view of the preferred embodiment to illustrate another state where the handle is disposed at the non-stacked position and where the face cover is disposed at a second position;

FIG. 9 is a fragmentary sectional view of the preferred embodiment to illustrate yet another state where the handle is disposed at a stacked position and where the face cover is disposed at the second position; and

FIG. 10 is a fragmentary sectional view of the preferred embodiment to illustrate still another state where the handle is disposed at the stacked position and where the front cover is disposed at the first position.

### DETAILED DESCRIPTION OF THE PREFERRED EMBODIMENT

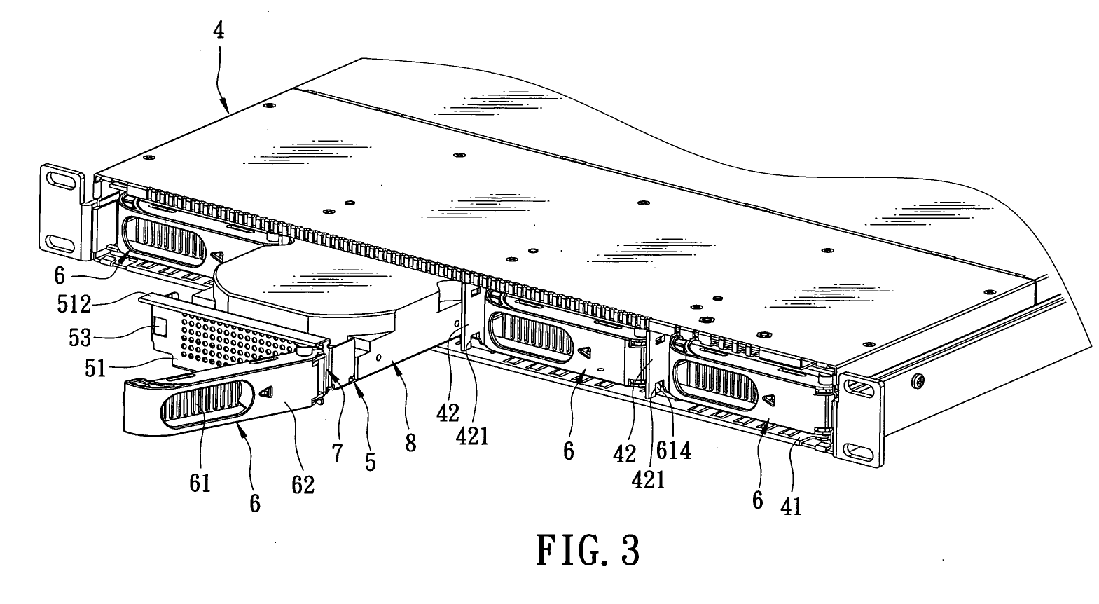

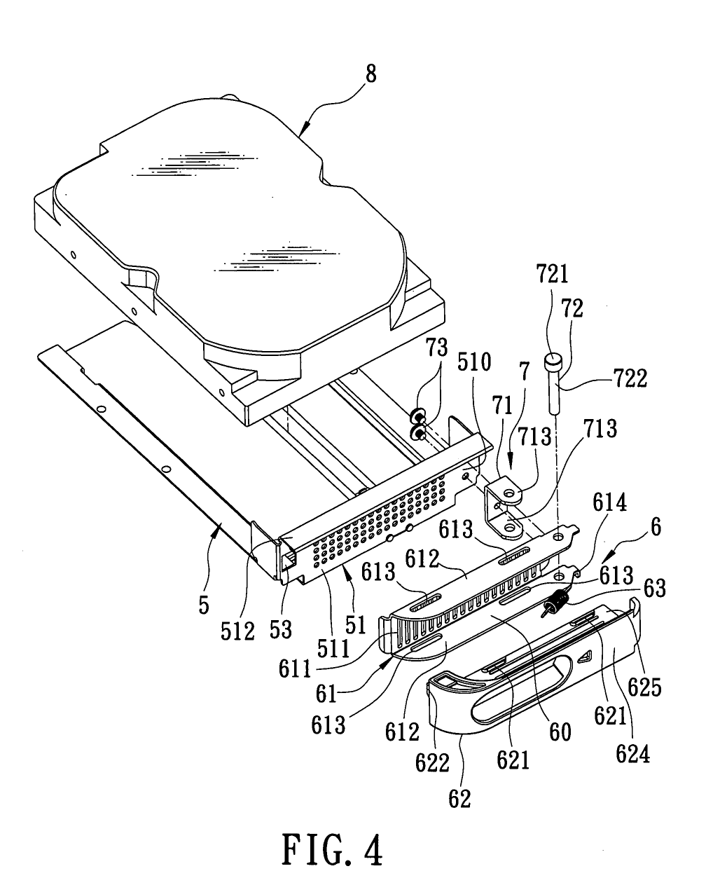

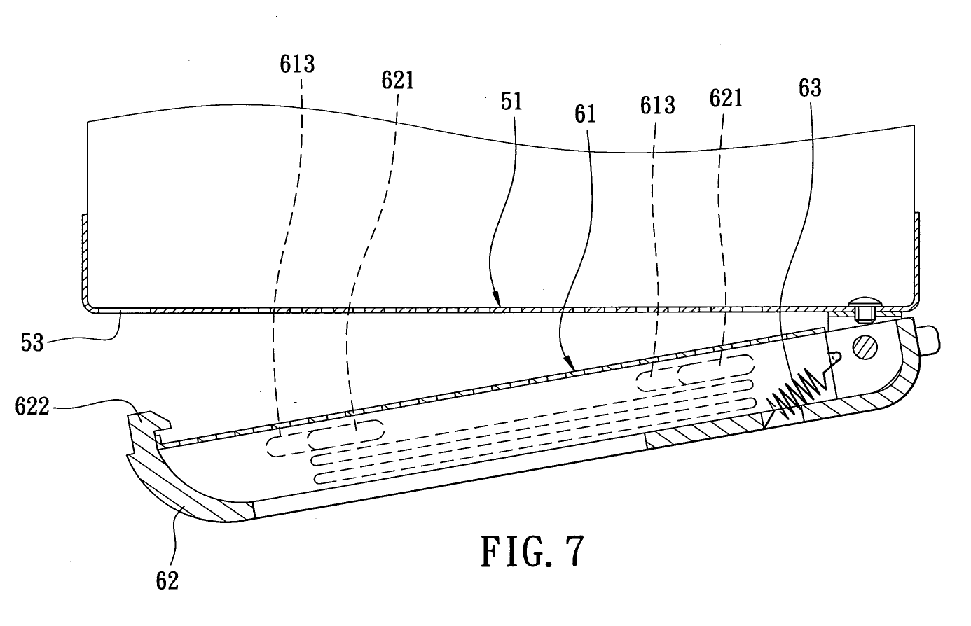

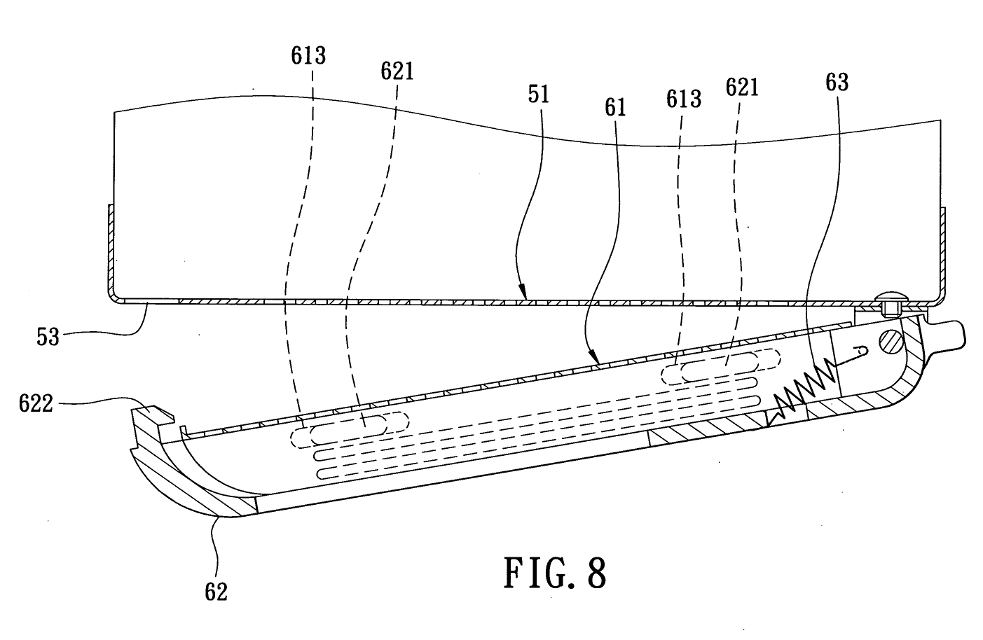

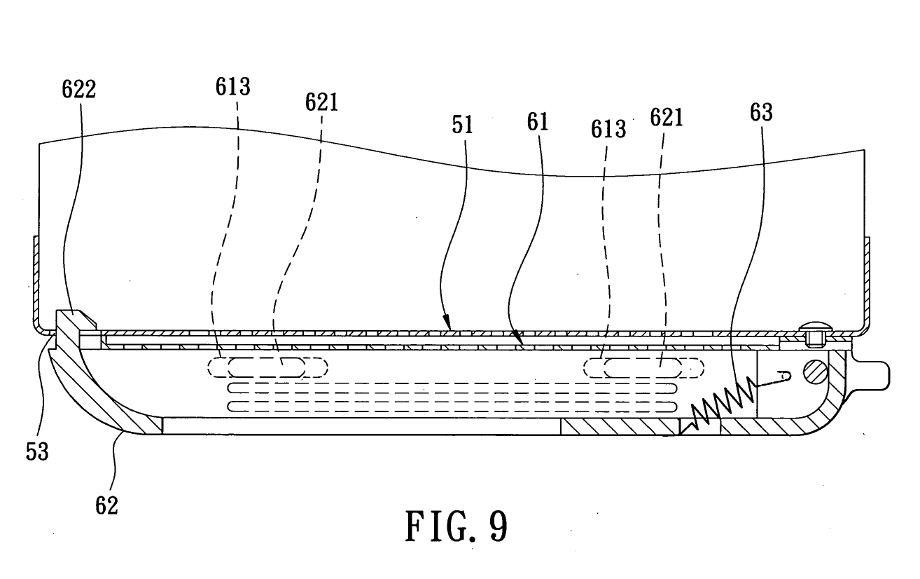

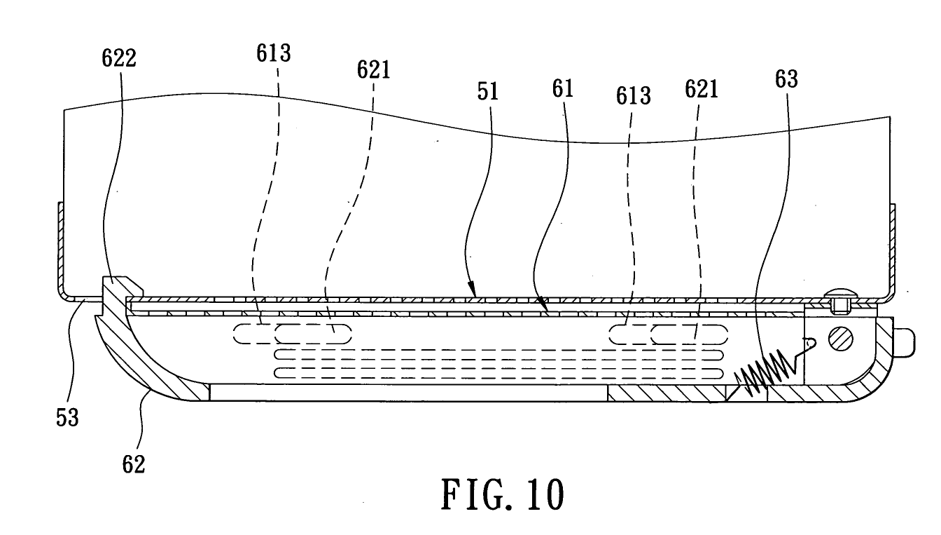

Referring to FIGS. 3 and 4, the preferred embodiment of a drawable tray assembly according to the present invention is shown to support a data storage device 8 thereon. The drawable tray assembly is insertable into an accommodating slot 41 of a storage casing 4, and comprises: a tray body 5 having a front end plate 51 that is formed with a first engaging member 53, the tray body 5 being adapted to support the data storage device 8 thereon; a pivot joint 7; a handle 6 including an elongated metal plate 61 that has a front side and that is pivoted to the front end plate 51 of the tray body 5 through the pivot joint 7 so as to permit the handle 6 to be rotatable relative to the tray body 5, the handle 6 further including a face cover 62 that covers and that is mounted slidably on the front side of the metal plate 61, that is co-rotatable with the metal plate 61, and that is formed with a second engaging member 622 which is releasably engageable with the first engaging member 53, the face cover 62 being slidable relative to the metal plate 61 along the length of the metal plate 61 between a first position (see FIGS. 7 and 10), where the second engaging member 622 engages the first engaging member 53, thereby preventing rotation of the handle 6 relative to the tray body 5, and a second position (see FIGS. 8 and 9), where the second engaging member 622 is disengaged from the first engaging member 53, thereby permitting rotation of the handle 6 relative to the tray body 5; and an urging member 63 interconnecting the metal plate and the face cover 62 for restoring the face cover 62 from the second position to the first position.

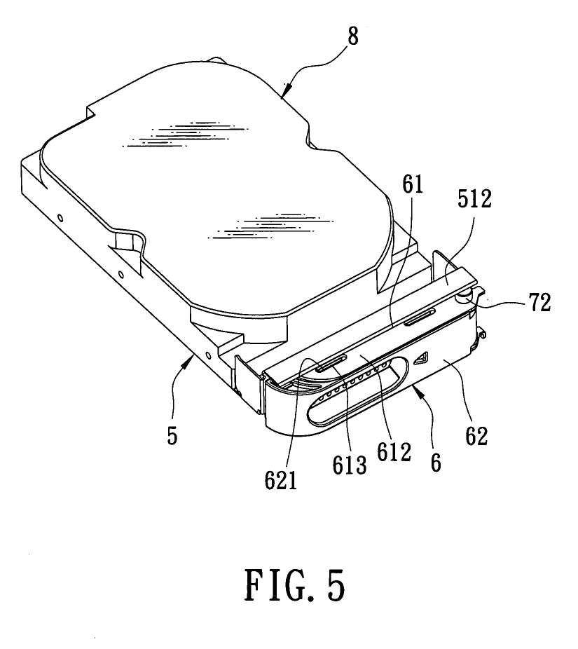

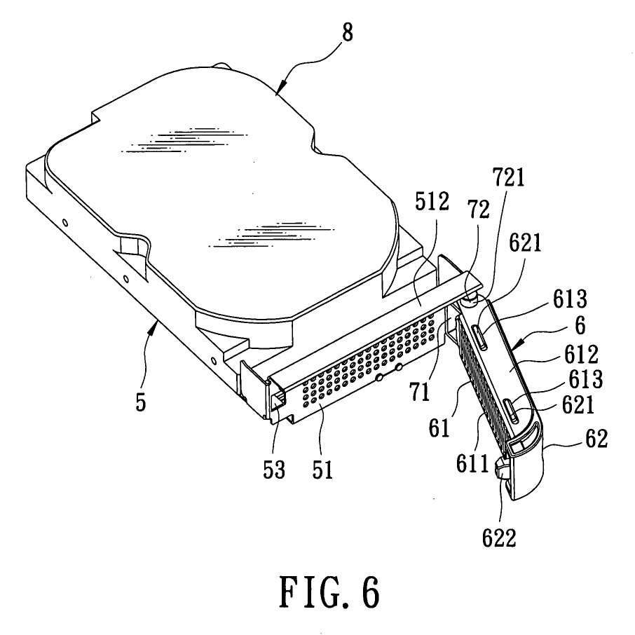

In this embodiment, the metal plate 61 has a base portion 611 and two opposite wing portions 612 extending transversely from the base portion 611. The handle 6 is rotatable relative to the tray body 5 between a stacked position (see FIG. 5), in which the base portion 611 of the metal plate 61 overlaps and is substantially parallel to the front end plate 51 of the tray body 5, and a non-stacked position (see FIG. 6), in which the base portion 611 of the metal plate 61 is inclined relative to the front end plate 51 of the tray body 5.

Referring again to FIG. 4, each of the wing portions 612 of the metal plate 61 is formed with a pair of elongated guiding holes 613, and the wing portions 612 of the metal plate 61 cooperatively define an elongated guiding trough 60 therebetween. The face cover 62 has a front face plate 624 and a pair of wing plates 625 that extend transversely from the front face plate 624 into the guiding trough 60. Each of the wing plates 625 is formed with a pair of guiding protrusions 621 that extend respectively through the guiding holes 613 in a respective one of the wing portions 612 of the metal plate 61 so as to permit sliding movement of the face cover 62 on the metal plate 61.

The front end plate 51 of the tray body 5 has a vertical plate portion 511 and a brim portion 512 that extends transversely from and that cooperates with the vertical plate portion 511 to define an accommodating recess 510 therebetween. The base portion 611 of the metal plate 61 is received in the accommodating recess 510, and is substantially parallel to the vertical plate portion 511 when the handle 6 is disposed at the stacked position.

The pivot joint 7 includes a U-shaped plate 71 that is secured to the vertical plate portion 511 of the front end plate 51 through fasteners 73 and that has upper and lower arm portions 713 extending into the guiding trough 60. The pivot joint 7 further includes a pivot pin 72 having a head portion 721 and a shank portion 722 extending from the head portion 721 through the upper and lower arm portions 713 of the U-shaped plate 71 and the wing portions 612 of the metal plate 61. The brim portion 512 of the front end plate 51 of the tray body 5 is disposed over and adjacent to the head portion 721 of the pivot pin 72 so as to prevent undesired removal of the pivot pin 72 from occurring.

The first and second engaging members 53, 622 engage each other in a tongue-and-groove engaging manner. In this embodiment, the front end plate 51 is formed with a through-hole that defines the first engaging member 53. The face cover 62 has a curved end that is formed with a protrusion which defines the second engaging member 622.

The metal plate 61 has an end protrusion 614 that is adapted to engage a retaining hole 421 in a vertical partition plate 42 of the storage casing 4 when the drawable tray assembly is inserted into the accommodating slot 41 of the storage casing 4, as best shown in FIG. 3.

Referring to FIG. 3, during insertion of the drawable tray assembly into the accommodating slot 41 of the storage casing 4, the handle 6 is first moved to the non-stacked position (see FIG. 6). When the drawable tray assembly is fully received in the accommodating slot 41, the handle 6 is moved from the non-stacked position toward the stacked position and the face cover 62 is subsequently moved by the user's hand from the first position to the second position (see FIGS. 7 and 8) so as to permit further movement of the handle 6 to the stacked position (see FIG. 9). After the handle 6 is positioned at the stacked position, the face cover 62 is released, and is subsequently restored from the second position (see FIG. 9) to the first position (see FIG. 10) by the urging action of the urging member 63, thereby resulting in engagement between the first and second engaging members 53, 622. When the drawable tray assembly is to be taken out of the storage casing 4, the face cover 62 is first moved to the second position (see FIG. 9) so as to result in disengagement between the first and second engaging members 53, 622, followed by moving the handle 6 to the non-stacked position (see FIG. 8) so as to disengage the end protrusion 614 of the metal plate 61 from the retaining hole 421 in the vertical partition plate 42 and so as to facilitate withdrawal of the drawable tray assembly from the storage casing 4.

During assembly of the handle 6 to the front end plate 51 of the tray body 5, the U-shaped plate 71 is first secured to the front end plate 51, and the face cover 62 is mounted to the metal plate 61 by extending the guiding protrusions 621 into the guiding holes 613, followed by mounting the handle 6 to the U-shaped plate 71 through the pivot pin 72. As such, assembly of the drawable tray assembly of this invention is easier and less expensive than that of the aforesaid conventional drawable tray assemblies.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A drawable tray assembly for supporting a data storage device thereon, said drawable tray assembly being insertable into an accommodating slot of a storage casing and comprising:
a tray body having a front end plate that is formed with a first engaging member, said tray body being adapted to support the data storage device thereon;
a pivot joint; and
a handle including an elongated metal plate that has a front side and that is pivoted to said front end plate of said tray body through said pivot joint so as to permit said handle to be rotatable relative to said tray body, said handle further including a face cover that covers and that is mounted slidably on said front side of said metal plate, that is co-rotatable with said metal plate, and that is formed with a second engaging member which is releasably engageable with said first engaging member.

2. The drawable tray assembly as claimed in claim 1, wherein said metal plate has a base portion and two opposite wing portions extending transversely from said base portion, said handle being rotatable relative to said tray body between a stacked position, in which said base portion of said metal plate overlaps and is substantially parallel to said front end plate of said tray body, and a non-stacked position, in which said base portion of said metal plate is inclined relative to said front end plate of said tray body.

3. The drawable tray assembly as claimed in claim 2, wherein each of said wing portions of said metal plate is formed with a pair of elongated guiding holes, said wing portions of said metal plate cooperatively defining an elongated guiding trough therebetween, said face cover having a front face plate and a pair of wing plates that extend transversely from said front face plate into said guiding trough.

4. The drawable tray assembly as claimed in claim 3, wherein each of said wing plates is formed with a pair of guiding protrusions that extend respectively through said guiding holes in a respective one of said wing portions of said metal plate so as to permit sliding movement of said face cover on said metal plate.

5. The drawable tray assembly as claimed in claim 4, wherein said front end plate of said tray body has a vertical plate portion and a brim portion that extends transversely from and that cooperates with said vertical plate portion to define an accommodating recess therebetween, said base portion of said metal plate being received in said accommodating recess and being substantially parallel to said vertical plate portion when said handle is disposed at the stacked position.

6. The drawable tray assembly as claimed in claim 5, wherein said pivot joint includes a U-shaped plate secured to said vertical plate portion of said front end plate of said tray body and having upper and lower arm portions that extend into said guiding trough, said pivot joint further including a pivot pin extending through said upper and lower arm portions and said wing portions of said metal plate.

7. The drawable tray assembly as claimed in claim 6, wherein said pivot pin has a head portion and a shank portion extending from said head portion through said upper and lower arm portions and said wing portions of said metal plate, said brim portion of said front end plate of said tray body being disposed over and adjacent to said head portion of said pivot pin so as to prevent undesired removal of said pivot pin.

8. The drawable tray assembly as claimed in claim 1, wherein said first and second engaging members engage each other in a tongue-and-groove engaging manner.

9. The drawable tray assembly as claimed in claim 1, wherein said metal plate has an end protrusion that is adapted to engage a retaining hole in the storage casing when said drawable tray assembly is inserted into the accommodating slot of the storage casing.

10. The drawable tray assembly as claimed in claim 1, wherein said face cover is slidable relative to said metal plate between first and second positions, said drawable tray assembly further comprising an urging member interconnecting said metal plate and said face cover for restoring said face cover from the second position to the first position.
